(19) United States
(12) Patent Application Publication
(10) Pub. No.: US 2006/0063314 A1
(43) Pub. Date: Mar. 23, 2006

(54) Field effect transistor and method of manufacturing the same

(75) Inventor: Akira Hokazono, Kawasaki-Shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/203,402

(22) Filed: Aug. 15, 2005

(30) Foreign Application Priority Data
Sep. 17, 2004 (JP) 2004-272166

(51) Int. Cl. H01L 21/8232

(52) U.S. Cl. 438/142

(57) ABSTRACT

A field effect transistor according to one embodiment of the present invention is a field effect transistor which is supposed to be operated under a temperature condition at 300 K or less, comprising: an n-channel field effect transistor having a gate electrode formed by a gate electrode material having a work function WFn of less than 4.05. A field effect transistor according to one embodiment of the present invention is a field effect transistor which is supposed to be operated under a temperature condition at 300 K or less, comprising: a p-channel field effect transistor having a gate electrode formed by a gate electrode material having a work function WFp of more than 5.17.

### CROSS-REFERENCE TO RELATED APPLICATION

The subject application is related to subject matter disclosed in Japanese Patent Application No. 2004-272166 filed on Sep. 17, 2004 in Japan to which the subject application claims priority under Paris Convention and which is incorporated herein by reference.

### BACKGROUND OF THE INVENTION

1. Field of the Invention

The present invention relates to a field effect transistor and a method of manufacturing the same and, more particularly, to a field effect transistor having a construction corresponding to a low-temperature operation to achieve high performance of a semiconductor integrated circuit and a method of manufacturing the field effect transistor.

2. Related Background Art

As a measure for improving mobility and reducing a parasitic resistance to improve the performance of a MOSFET (field effect transistor), a device is operated at a low temperature equal to or lower than a room temperature.

However, a MOSFET has a characteristic feature in which a threshold voltage increases with a decrease in operation temperature.

FIG. 1 is a graph showing a threshold voltage characteristic of the MOSFET with respect to an operation temperature.

In the graph in FIG. 1, results obtained by measuring threshold voltages Vthn (Vds=5 mV), Vthn (Vds=1.2 V), Vthp (Vds=−1.2 V), Vthp (Vds=−5 mV) (V) of n-channel MOSFETs having drain voltages Vds of 5 mV and 1.2 V and p-channel MOSFETs having drain voltages Vds of −1.2 V and −5 mV at various measurement temperatures (K). The gate lengths Lg of the MOSFETs are 0.88 μm each.

According to the measurement results, change rates of the threshold voltages Vthn of the n-channel MOSFETs having the drain voltages Vds of 5 mV and 1.2 V are −0.55 mV/K and −0.51 mV/K, respectively, and change rates of the threshold voltages Vthp of the p-channel MOSFETs having the drain voltages Vds of −1.2 V and −5 mV are 0.80 mV/K and 0.71 mV/K, respectively.

That is, as is also apparent from the shapes of line graphs, both the absolute values of the threshold voltages of the n-channel MOSFETs and the p-channel MOSFETs also increase with the decrease in operation temperature. The absolute values of the threshold voltages increase by about 50 to 80 mV when the operation temperature decreases by 100 K.

Therefore, in order to accurate and reliably operate a MOSFET, the threshold voltage of the MOSFET must be controlled depending on an operation temperature.

In order to decrease the absolute value of the threshold voltage of the MOSFET, the concentration of ion implantation in a channel may be decreased. However, an impurity concentration of the channel is sufficiently high under only normal well conditions. For this reason, a margin for control of the threshold voltage depending on the channel conditions is not large.

As another method of controlling the threshold voltage of the MOSFET, a substrate bias voltage Vsub, i.e., a forward voltage between a source and a substrate may be applied.

However, when the substrate bias voltage Vsub is applied to the MOSFET, a junction capacitance disadvantageously increases, or a forward current between the source and the substrate, i.e., a drain current Ids disadvantageously flows.

FIG. 2 is a graph showing a gate voltage Vgs-drain current Ids characteristic with respect to a change of the substrate bias voltage Vsub of the MOSFET.

In the measurement of the graph in FIG. 2, an n-channel MOSFET having a gate length Lg=0.41 μm is used, and a power supply voltage Vdd and a measurement temperature are set at 1.2 V and 223 K, respectively.

Gate voltage Vgs-drain current Ids characteristics obtained when the substrate bias voltage Vsub applied to the MOSFET is changed from −0.2 V to 1.0 V every 0.2 V, i.e., −0.2 V, 0 V, 0.2 V, 0.4 V, 0.6 V, 0.8 V, and 1.0 V are measured.

As shown in the graph in FIG. 2, when the substrate bias voltage Vsub is gradually increased, especially, when the substrate bias voltage Vsub of 0.8 to 1.0 V is applied, a sufficiently large drain current Ids flows even though no gate voltage Vgs is applied.

Such a current characteristic indicates that a forward current continuously flows between the source and the substrate even though a MOSFET is in an off state. The current characteristic causes a problem that increases a power consumption.

When a substrate bias voltage Vsub for controlling a threshold voltage is applied to the p-channel MOSFET, a hot-carrier resistance is improved. However, a similar substrate bias voltage Vsub is applied to an n-channel MOSFET to cause a problem that deteriorates a hot-carrier resistance.

### SUMMARY OF THE INVENTION

According to a first aspect of an one embodiment of a field effect transistor according to the present invention, there is provided a field effect transistor which is supposed to be operated under a temperature condition at 300 K or less, comprising:
an n-channel field effect transistor having a gate electrode formed by a gate electrode material having a work function WFn of less than 4.05.

According to a second aspect of an one embodiment of a field effect transistor according to the present invention, there is provided a field effect transistor which is supposed to be operated under a temperature condition at 300 K or less, comprising:
an n-channel field effect transistor having a gate electrode formed by a gate electrode material having a work function WFn which is less than a numerical value corresponding to an energy Ec at a lower end of a conduction band in an energy band.

According to a third aspect of an one embodiment of a field effect transistor according to the present invention, there is provided a field effect transistor which is supposed to be operated under a temperature condition at 300 K or less, comprising:
a p-channel field effect transistor having a gate electrode formed by a gate electrode material having a work function WFp of more than 5.17.

According to a fourth aspect of an one embodiment of a field effect transistor according to the present invention, there is provided a field effect transistor which is supposed to be operated under a temperature condition at 300 K or less, comprising:
a p-channel field effect transistor having a gate electrode formed by a gate electrode material having a work function WFp which exceeds a numerical value corresponding to an energy Ev at an upper end of a valence band in an energy band.

According to a first aspect of an one embodiment of a method of manufacturing a field effect transistor according to the present invention, there is provided a method of manufacturing a field effect transistor which is supposed to be operated under a temperature condition at 300 K or less, wherein a gate electrode of an n-channel field effect transistor is formed by a gate electrode material having a work function WFn of less than 4.05.

According to a second aspect of an one embodiment of a method of manufacturing a field effect transistor according to the present invention, there is provided a method of manufacturing a field effect transistor which is supposed to be operated under a temperature condition at 300 K or less, wherein a gate electrode of an n-channel field effect transistor is formed by a gate electrode material having a work function WFn which is less than a numerical value corresponding to an energy Ec at a lower end of a conduction band in an energy band.

According to a third aspect of an one embodiment of a method of manufacturing a field effect transistor according to the present invention, there is provided a method of manufacturing a field effect transistor which is supposed to be operated under a temperature condition at 300 K or less, wherein a gate electrode of a p-channel field effect transistor is formed by a gate electrode material having a work function WFp of more than 5.17.

According to a fourth aspect of an one embodiment of a method of manufacturing a field effect transistor according to the present invention, there is provided a method of manufacturing a field effect transistor which is supposed to be operated under a temperature condition at 300 K or less, wherein a gate electrode of a p-channel field effect transistor is formed by a gate electrode material having a work function WFp which exceeds a numerical value corresponding to an energy Ev at an upper end of a valence band in an energy band.

### BRIEF DESCRIPTION OF THE DRAWINGS

FIG. 1 is a graph showing a threshold voltage characteristic of the MOSFET with respect to an operation temperature;

FIG. 2 is a graph showing a gate voltage Vgs-drain current Ids characteristic with respect to a change of the substrate bias voltage Vsub of the MOSFET;

FIGS. 3A and 3B are graphs showing ranges of work functions of the gate electrode materials respectively used in the n-channel MOSFET and the p-channel MOSFET in the field effect transistor according to each of the embodiment of the present invention and the method of manufacturing the field effect transistor;

FIG. 4A is a sectional view showing a manufacturing step of the field effect transistor (n-channel MOSFET) according to the first embodiment of the present invention and FIG. 4B is a sectional view showing the same manufacturing step of the field effect transistor (p-channel MOSFET) according to the first embodiment of the present invention;

FIG. 5A is a sectional view showing a manufacturing step of the field effect transistor (n-channel MOSFET) according to the first embodiment of the present invention and FIG. 5B is a sectional view showing the same manufacturing step of the field effect transistor (p-channel MOSFET) according to the first embodiment of the present invention;

FIG. 6A is a sectional view showing a manufacturing step of the field effect transistor (n-channel MOSFET) according to the first embodiment of the present invention and FIG. 6B is a sectional view showing the same manufacturing step of the field effect transistor (p-channel MOSFET) according to the first embodiment of the present invention;

FIG. 7A is a sectional view showing a manufacturing step of the field effect transistor (n-channel MOSFET) according to the first embodiment of the present invention and FIG. 7B is a sectional view showing the same manufacturing step of the field effect transistor (p-channel MOSFET) according to the first embodiment of the present invention;

FIG. 8 is a sectional view showing a first example of a gate electrode forming method;

FIG. 9 is a sectional view showing a second example of the gate electrode forming method;

FIGS. 10A and 10B are sectional views showing a third example of the gate electrode forming method;

FIGS. 11A and 11B are sectional views showing a third example of the gate electrode forming method;

FIG. 12A is a sectional view showing a manufacturing step of the field effect transistor (n-channel MOSFET) according to the second embodiment of the present invention and FIG. 12B is a sectional view showing the same manufacturing step of the field effect transistor (p-channel MOSFET) according to the second embodiment of the present invention;

FIG. 13A is a sectional view showing a manufacturing step of the field effect transistor (n-channel MOSFET) according to the second embodiment of the present invention and FIG. 13B is a sectional view showing the same manufacturing step of the field effect transistor (p-channel MOSFET) according to the second embodiment of the present invention;

FIG. 14A is a sectional view showing a manufacturing step of the field effect transistor (n-channel MOSFET) according to the second embodiment of the present invention and FIG. 14B is a sectional view showing the same manufacturing step of the field effect transistor (p-channel MOSFET) according to the second embodiment of the present invention;

FIG. 15A is a sectional view showing a manufacturing step of the field effect transistor (n-channel MOSFET) according to the second embodiment of the present invention and FIG. 15B is a sectional view showing the same manufacturing step of the field effect transistor (p-channel MOSFET) according to the second embodiment of the present invention; and

FIG. 16A is a sectional view showing a manufacturing step of the field effect transistor (n-channel MOSFET) according to the second embodiment of the present invention and FIG. 16B is a sectional view showing the same manufacturing step of the field effect transistor (p-channel MOSFET) according to the second embodiment of the present invention.

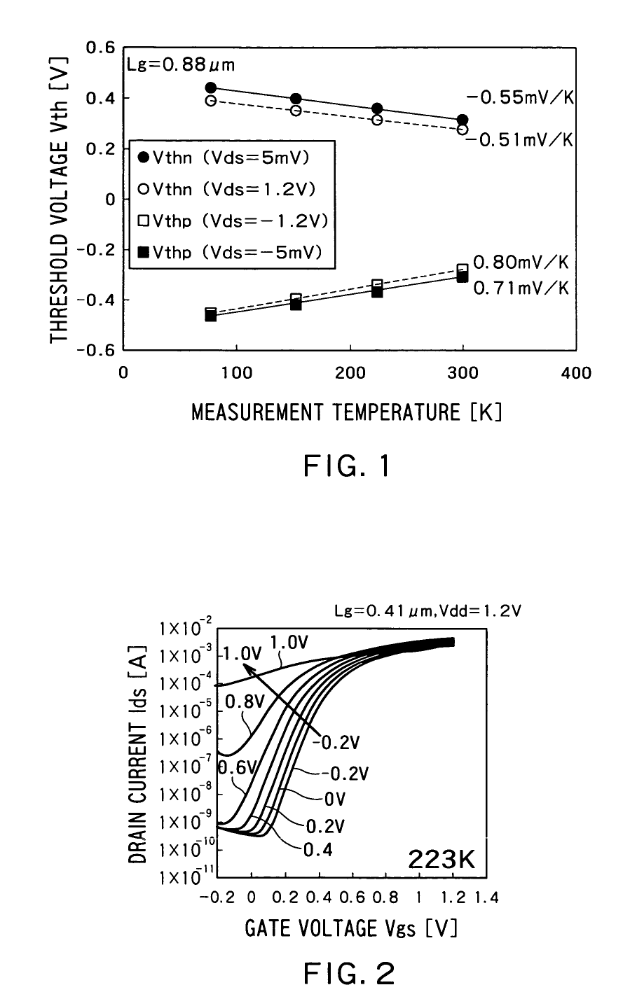

### DETAILED DESCRIPTION OF THE EMBODIMENTS

Embodiments of a field effect transistor (MOSFET) according to the present invention and a method of manufacturing the field effect transistor will be described below with reference to the drawings.

In each of field effect transistors according to the embodiments of the present invention and methods of manufacturing the field effect transistors, a gate electrode of a MOSFET is formed by a gate electrode material having a work function (to be also referred to as a “WF” hereinafter) falling within a range which is not conventionally used to control the threshold voltage of the MOSFET under a low-temperature condition without applying a substrate bias voltage Vsub.

The “low temperature” mentioned here is a temperature equal to or lower than a room temperature. As the “low temperature”, for example, 300 K, 260 K, 240 k, 200 K, 150 K, 77 K, 50 K, and the like are supposed.

In a field effect transistor according to each embodiment of the present invention and a method of manufacturing the field effect transistor, a gate electrode material having such a work function that a threshold voltage decreases in an operation of a MOSFET under the low-temperature condition is selected, or a gate electrode material is manufactured while controlling the threshold voltage. The gate electrode of the MOSFET is formed by the gate electrode material.

More specifically, it is assumed that, as a gate electrode material of an n-channel MOSFET, a material having a work function of less than 4.05 is used. When it is considered that the threshold voltage of the n-channel MOSFET changes by about 50 to 80 mV with respect to a temperature change of 100 K, a work function WFn of the gate electrode material of the n-channel MOSFET may satisfy the following inequality (1) with respect to a temperature Temp:
4.05−(300−Temp)×0.08/100<WFn<4.05−(300−Temp)×0.05/100 (1)

It is assumed that, as a gate electrode material of a p-channel MOSFET, a material having a work function exceeding 5.17 is used. When it is considered that the threshold voltage of the MOSFET changes by about 50 to 80 mV with respect to a temperature change of 100 K, a work function WFp of the gate electrode material of the p-channel MOSFET may satisfy the following inequality (2) with respect to a temperature Temp:
5.17+(300−Temp)×0.05/100<WFp<5.17+(300−Temp)×0.08/100 (2)

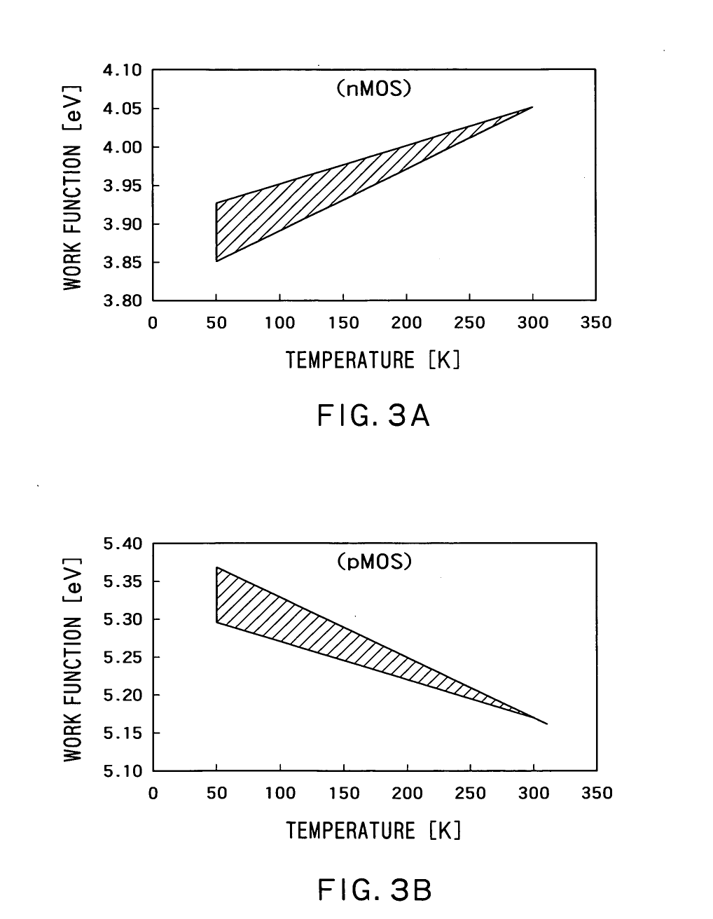

FIGS. 3A and 3B are graphs showing ranges of work functions of the gate electrode materials respectively used in the n-channel MOSFET and the p-channel MOSFET in the field effect transistor according to each of the embodiment of the present invention and the method of manufacturing the field effect transistor.

The range of the work function of the material used as the gate electrode material of the n-channel MOSFET is a range defined by the inequality (1), and is shown in FIG. 3A.

The range of the work function of the material used as the gate electrode material of the p-channel MOSFET is a range defined by the inequality (2), and is shown in FIG. 3B.

A work function WF of the material used as a gate electrode material of a conventional MOSFET is included in a range of 4.05 or more corresponding to an energy Ec at the lower end of a conduction band of an energy band to 5.17 or less corresponding to an energy Ev at the upper end of a valence band, i.e., 4.05≦WF≦5.17 without exception.

On the other hand, in the field effect transistor and the method of manufacturing the field effect transistor according to each of the embodiments of the present invention, as a gate electrode material for forming a gate electrode of a MOSFET, a gate electrode material having such a work function that a threshold voltage decreases in an operation of the MOSFET under the low-temperature condition is selected, or a gate electrode material is manufactured while controlling the threshold voltage.

As a gate electrode material of an n-channel MOSFET, a material having a work function of less than 4.05 is used. When an operation at a temperature of, e.g., 77 K is assumed, as the gate electrode material, titanium (Ti: WF=3.9), molybdenum (Mo: WF=3.9) into which argon ions (Ar⁺) are injected, tantalum nitride (TaN: WF=3.4 to 4.0) the work function of which is controlled by a nitrogen (N) concentration, and the like can be used.

As a gate electrode material of a p-channel MOSFET, a material having a work function of larger than 5.17 is used. When an operation at a temperature of, e.g., 77 K is assumed, as the gate electrode material, titanium nickel (TiNi: WF=5.3), nickel germanium (NiGe: WF=5.2), platinum (Pt=5.2), and the like can be used.

Since a change rate of the threshold voltage of the MOSFET is uniquely determined by a temperature, a gate electrode material having an appropriate work function is selected depending on an assumed operation temperature, or a gate electrode material is manufactured while controlling the work function depending on an assumed operation temperature.

When a device, such as a field effect transistor according to each of the embodiment of the present invention, designed for a low-temperature operation is operated at a room-temperature condition, a reverse bias voltage is applied such that a reverse bias is set between the source and the substrate. In this case, even when the MOSFET is in an off state, a problem that causes a forward current to flow between the source and the substrate does not occur on the device structure.

As described above, the hot-carrier resistance is improved by applying the substrate bias voltage Vsub in the p-channel MOSFET On the other hand, the hot-carrier resistance is deteriorated by applying the substrate bias voltage Vsub in the n-channel MOSFET.

In consideration of the hot-carrier resistance of the device, the following setting may be performed. That is, the substrate bias voltage Vsub is applied only to the p-channel MOSFET to control a threshold voltage, and no substrate bias voltage Vsub is applied to the n-channel MOSFET.

Therefore, when this setting is performed, no substrate bias voltage Vsub is applied to the n-channel MOSFET so that the material having the work function is used as the gate electrode material. On the other hand, the substrate bias voltage Vsub is applied to the p-channel MOSFET, and the polysilicon (poly-Si), polysilicon germanium (poly-SiGe) obtained by mixing germanium in polysilicon, or the like as well as a conventional MOSFET is used as the gate electrode material.

The field effect transistors according to the embodiments of the present invention will be described below in detail with reference to the manufacturing steps of the field effect transistors.

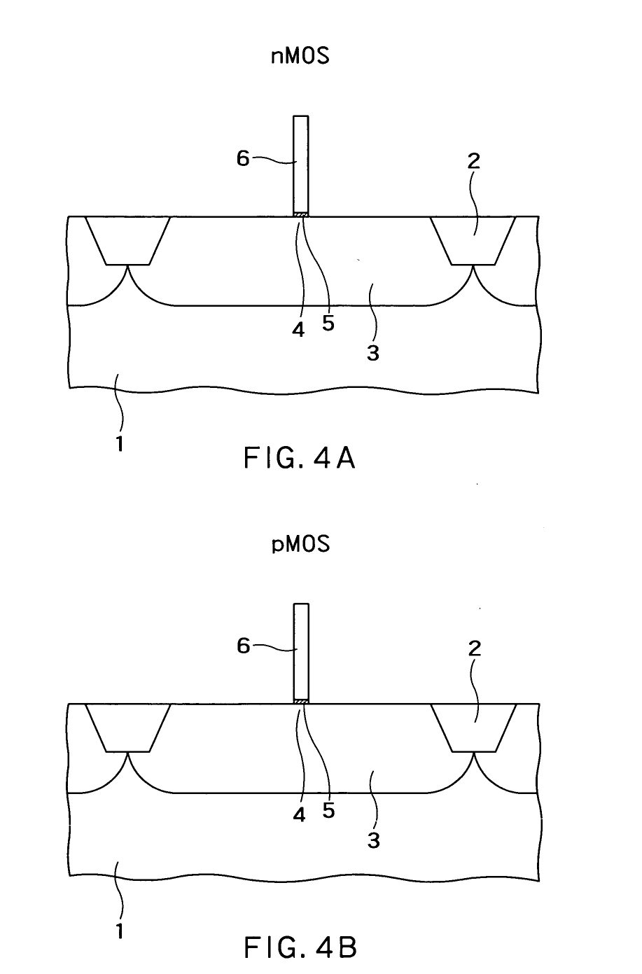

FIGS. 4A and 4B to FIGS. 7A and 7B are sectional views showing the manufacturing steps of the field effect transistor according to the first embodiment of the present invention. Respective Figs. A show n-channel MOSFETs, and respective Figs. B show p-channel MOSFETs.

In the field effect transistor according to the first embodiment of the present invention, the substrate bias voltage Vsub for controlling threshold voltages is not applied to an n-channel MOSFET and a p-channel MOSFET, and as the gate electrode materials for forming the gate electrode, the gate electrode materials having the work functions described with reference to FIGS. 3A and 3B so as to decrease the threshold voltages in the operations of the MOSFETs under the supposed low-temperature condition are selected, or the gate electrode materials are manufactured while controlling the work functions, and the gate electrodes are formed by the gate electrode materials, respectively.

As shown in FIGS. 4A and 4B, a device isolation insulating film 2 having a depth of 2000 to 3500 Å is formed on an n-type or p-type silicon substrate 1 by a burying device isolation insulating method.

In an active device portion between the device isolation insulating films 2, an oxide film having a thickness of 200 Å or less is formed on the surface of the silicon substrate 1. Subsequently, ion implantation and activation RTA (Rapid thermal Annealing) for forming a well region 3 and a channel region 4 are performed. As typical ion implantation conditions, phosphorous (P) ions are implanted in an n-type well at an acceleration voltage of 500 KeV and a dose of 3.0×10¹³ ions/cm⁻², boron (B) ions are implanted in a channel in the n-type well at an acceleration voltage of 10 KeV and a dose of 1.5×10¹³ ions/cm⁻², boron (B) ions are implanted into a p-type well, and arsenic (As) ions are implanted into a channel in the p-type well at an acceleration voltage of 80 KeV and a dose of 1.0×10¹³ ions/cm⁻².

Thereafter, a gate insulating film 5 having a thickness of 5 to 60 Å is formed by a thermal oxidation method or an LPCVD (Low Pressure Chemical Vapor Deposition) method. A gate electrode material is deposited in a thickness of 500 to 2000 Å, and gate patterning is performed in order that the gate electrode material has a gate length of 100 to 1500 Å by a photolithography method, an X-ray lithography method, or an electron-beam lithography method to form a gate electrode 6 (see FIGS. 4A and 4B).

In the field effect transistor according to the first embodiment of the present invention, gate electrode materials having such work functions that threshold voltages decrease in operations under a supposed low-temperature condition are selected, or gate electrode materials are manufactured while controlling the threshold voltages for an n-channel MOSFET and a p-channel MOSFET, respectively, and gate electrodes of the n-channel MOSFET and the p-channel MOSFET are formed by the gate electrode materials, respectively. In the embodiment, the gate electrodes of the n-channel MOSFET and the p-channel MOSFET must be formed by appropriate electrode materials, therefore, different electrode materials, respectively.

As a method of forming the gate electrode, in addition the method of forming the gate electrode by the patterning, several forming methods such as a method of forming a dummy gate to form the gate electrode by a Damascene gate process can be used. For this reason, formation of the gate electrode will be described below in detail.

In FIGS. 4A and 4B to FIGS. 7A and 7B, the gate electrodes 6 formed in an n-channel MOSFET region and a p-channel MOSFET region are shown. By the steps of forming a gate electrode to be described later, the gate electrodes of the n-channel MOSFET and the p-channel MOSFET are formed by different electrode materials, respectively.

As the gate insulating film 5, in addition to a film of silicon oxide (SiO₂), a film of silicon oxide nitride (SiON), silicon nitride (SiN), high-dielectric tantalum oxide (Ta₂O₅), a hafnium oxide (HfO₂), or the like may be formed.

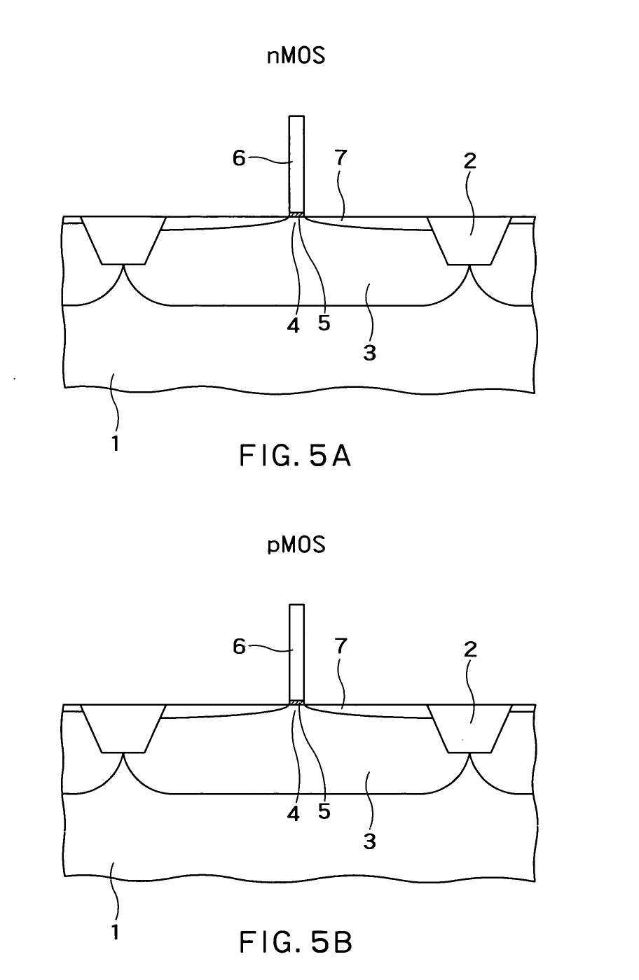

After the gate electrodes 6 are formed, as shown in FIGS. 5A and 5B, a shallow diffusion layer 7 is formed. Examples of conditions set when the diffusion layer 7 is formed are as follows. When the diffusion layer 7 is of an n type, for example, arsenic (As) ions are implanted at an acceleration voltage of 1 to 5 KeV and a dose of 5.0×10¹⁴ to 1.5×10¹⁵ ions/cm⁻². When the diffusion layer 7 is of a p type, for example, boron fluoride (BF₂) ions or boron (B) ions are implanted at an acceleration voltage of 1 to 3 KeV and a dose of 5.0×10¹⁴ to 1.5×10¹⁵ ions/cm⁻². Thereafter, activation RTA is performed (see FIGS. 5A and 5B).

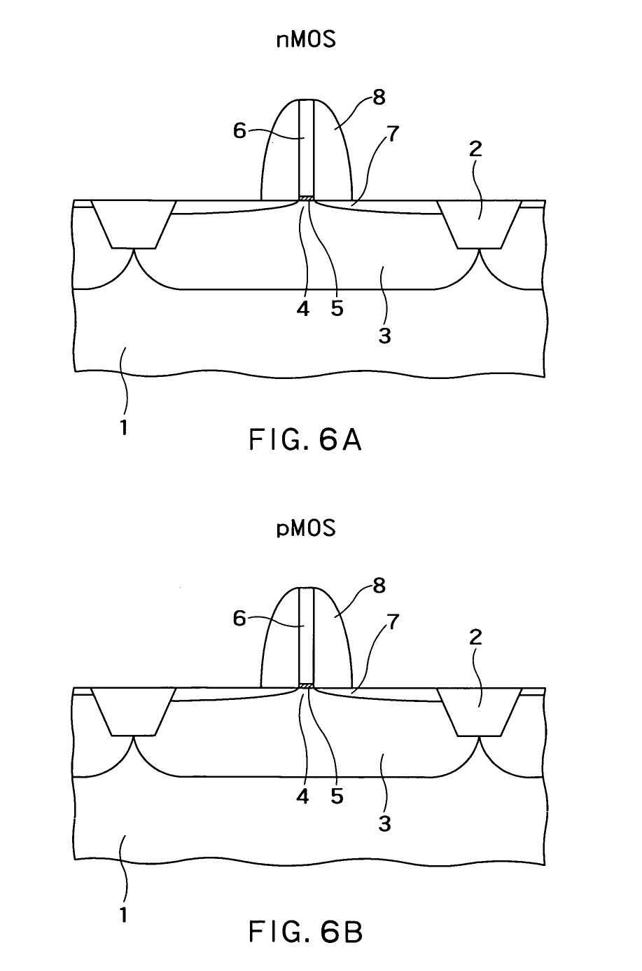

After the diffusion layer 7 is formed, as shown in FIGS. 6A and 6B, a gate side wall 8 is formed.

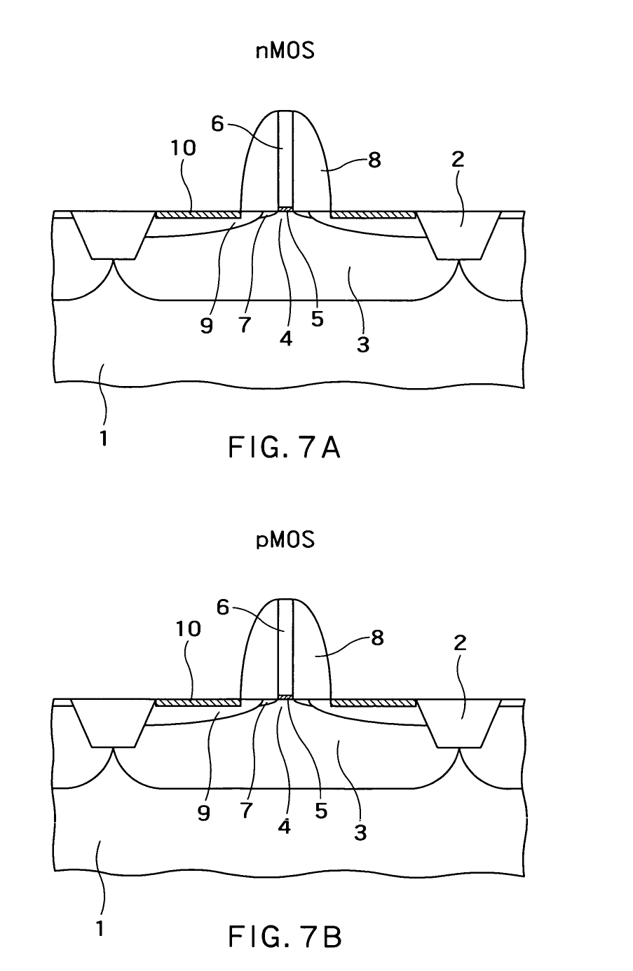

After the gate side wall 8 is formed, as shown in FIGS. 7A and 7b, a high-concentration diffusion layer 9 is formed to perform activation RTA. Furthermore, hydrofluoric acid treatment is performed to remove a natural oxide film, and a silicide layer 10 is formed on the surface portion of the high-concentration diffusion layer 9. When a nickel (Ni) silicide layer is formed, a nickel (Ni) layer is deposited by sputtering, and RTA for silicidation is performed. After RTA at a temperature of 400 to 500° C. is performed to form a nickel silicide layer, when etching is performed by a mixed solution of sulfuric acid and hydrogen peroxide solution, a salicide (self-aligned silicide) process performed by formation of the nickel silicide layer is completed. As respectively shown in FIGS. 7A and 7B, main parts of the n-channel MOSFET and the p-channel MOSFET are completed.

After a nickel (Ni) layer is deposited by sputtering, a titanium nitride (TiN) layer may be deposited. Alternatively, a two-step annealing process may be employed. In that case, after the nickel (Ni) layer is deposited by sputtering, low-temperature RTA at a temperature of 250 to 400° C. is performed once, etching is then performed by a mixed solution of sulfuric acid and hydrogen peroxide solution, and RTA at a temperature of 400 to 500° C. is performed again for a low sheet resistance.

Before and after formation of the high-concentration diffusion layer 9, a selective epitaxial growth process for a silicon layer or a selective growth process for a silicon germanium layer may be performed.

When the gate electrode 6 is formed by a metal, silicide formation is not performed on the gate electrode 6.

In manufacturing a CMOS device, after sectional structures shown in FIGS. 7A and 7B are completed, a film having a high selectivity in RIE for an interlayer film is formed on the silicide layer 10 to prevent a junction leak characteristic from being deteriorated by etching the silicide layer 10 by RIE (Reactive Ion Etching) for forming a contact hole.

Thereafter, TEOS (Tetra Ethyl Ortho Silicate or Tetra Ethoxy Silane: Si(OCH₂CH₃)₄), BPSG (Borophospho Silicate Glass), silicon nitride (SiN), and the like are deposited as an interlayer film, and CMP (Chemical Mechanical Polishing) for planarization is performed.

After CMP is performed, in a state in which a resist mask is formed by a lithography method, RIE is performed to form contact holes, and a titanium (Ti) layer, a titanium nitride (TiN) layer, and the like are deposited as a barrier metal. Furthermore, after a tungsten (W) layer is selectively grown or formed on the entire surface, CMP is performed.

Finally, a metal layer serving as a wiring is deposited and then patterned for wiring by a lithography method, thereby completing a CMOS device.

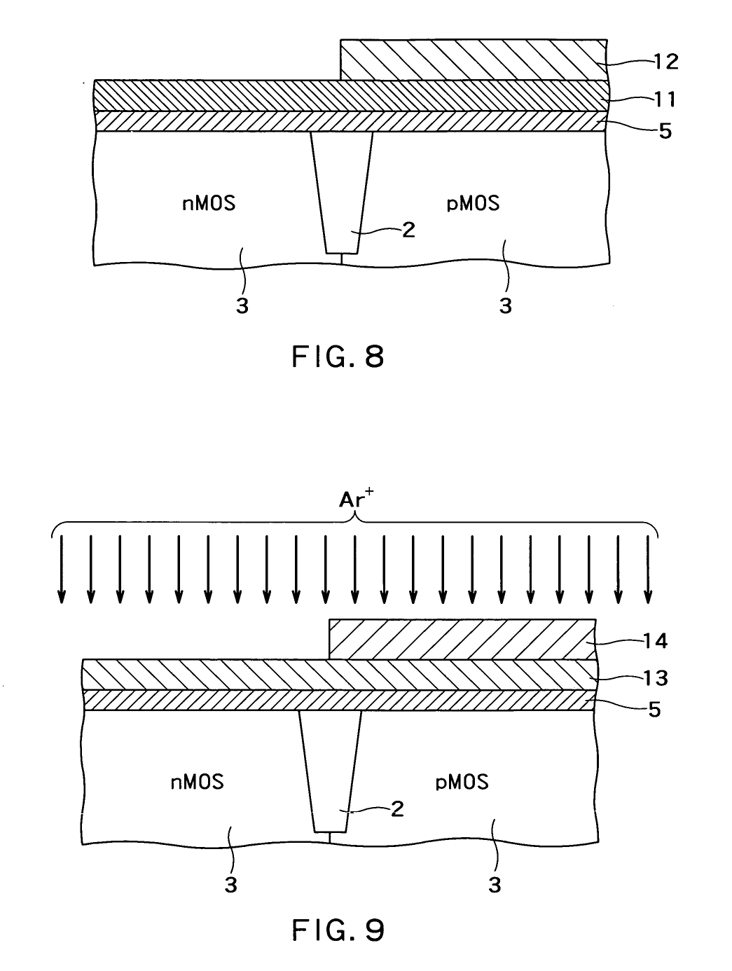

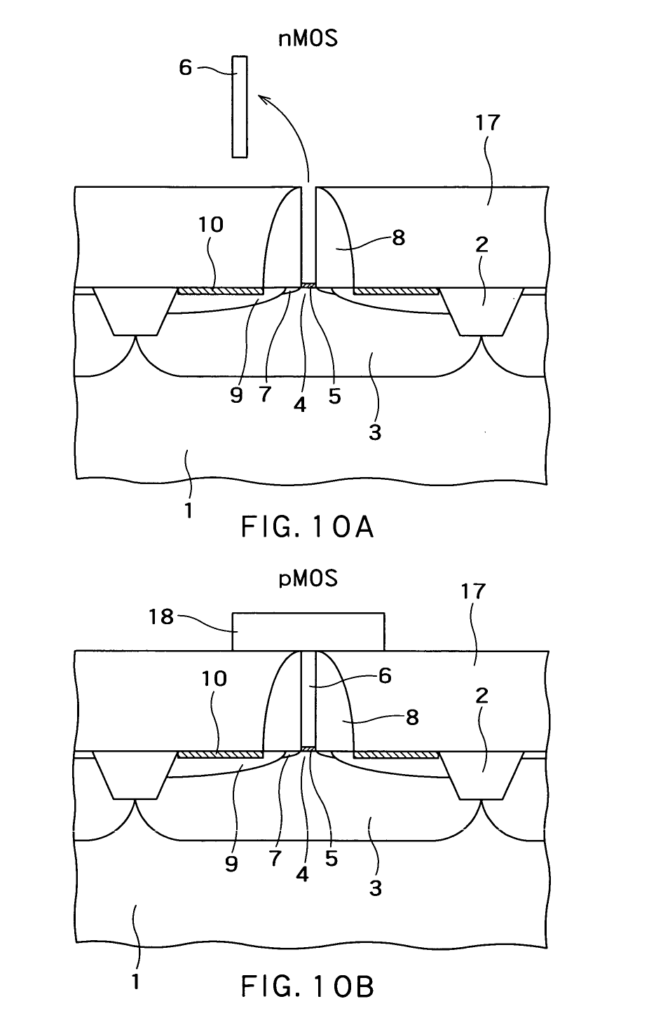

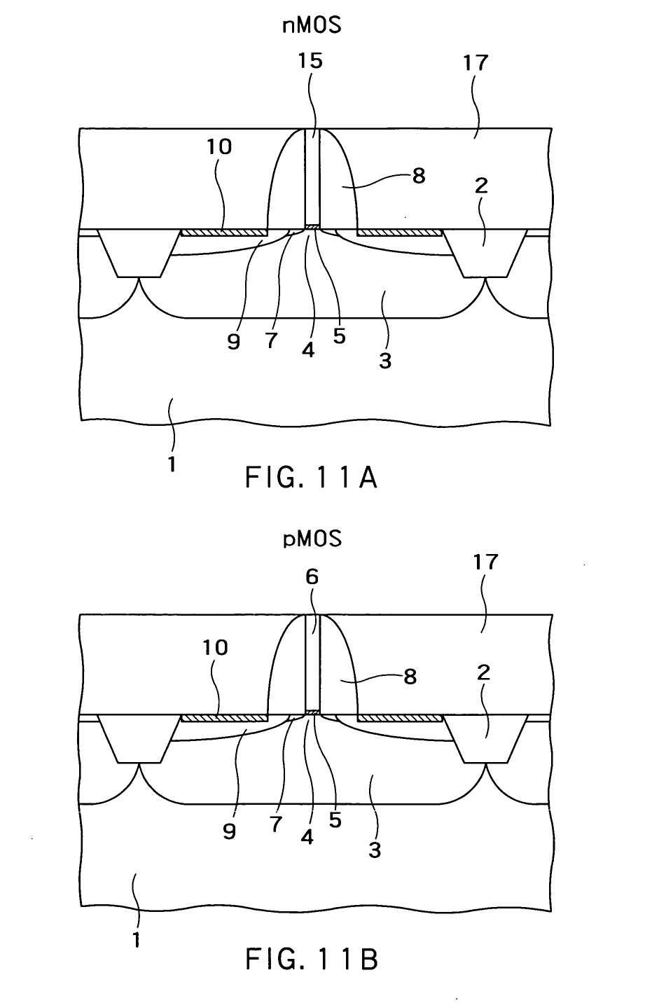

FIG. 8 is a sectional view showing a first example of a gate electrode forming method. FIG. 9 is a sectional view showing a second example of the gate electrode forming method. FIGS. 10A and 10B and FIGS. 11A and 11B are sectional views showing a third example of the gate electrode forming method.

In the first example of the gate electrode forming method shown in FIG. 8, after the gate insulating film 5 is formed, a titanium (Ti) layer 11 is deposited on the gate insulating film 5 by sputtering, furthermore, a nickel (Ni) layer 12 is deposited thereon by sputtering, a resist mask is formed in a p-channel MOSFET region, and a nickel layer 12 in an n-channel MOSFET region is removed.

After the resist mask is removed, a nitriding process is performed to form a nickel-titanium (NiTi) alloy film in a p-channel MOSFET region. Thereafter, gate processing is performed to form a gate electrode 6 comprising titanium (Ti) having a work function of 3.9 in the n-channel MOSFET region and to from a gate electrode 6 comprising nickel titanium (NiTi) having a work function of 5.3 in the p-channel MOSFET region.

In the second example of the gate electrode forming method shown in FIG. 9, after the gate insulating film 5 is formed, a molybdenum (Mo) layer 13 is deposited on the gate insulating film 5. Thereafter, the p-channel MOSFET region is coated with a resist mask 14, and argon ion (Ar⁺) is irradiated to make it possible to form a gate electrode 6 in which argon ions (Ar⁺) are implanted and which comprises molybdenum (Mo) having a work function of 3.9 in the n-channel MOSFET region.

On the other hand, in the p-channel MOSFET region, a gate electrode is formed by polysilicon germanium (poly-SiGe). Furthermore, the gate electrode is completely silicided as nickel silicide to make it possible to form a gate electrode 6 comprising nickel germanium (NiGe) having a work function of 5.2.

In the third example of the gate electrode forming method shown in FIGS. 10A and 10B and FIGS. 11A and 11B, for example, a gate electrode 6 is primarily formed in the p-channel MOSFET by a gate electrode material having an appropriate work function.

As shown in FIGS. 10A and 10B, after the interlayer film 17 is formed, CMP is performed to expose the upper surface of the gate electrode 6. A cap layer 18 comprising silicon oxide (SiO₂), silicon nitride (SiN), and the like is formed on the gate electrode 6 formed in the p-channel MOSFET region. Thereafter, the gate electrode 6 formed in the n-channel MOSFET region is removed by RIE or the like.

Thereafter, as shown in FIGS. 11A and 11B, a gate electrode material having an appropriate work function is buried in the n-channel MOSFET by, e.g., a Damascene process to make it possible to form a gate electrode 15.

As described above, according to the field effect transistor according to the first embodiment of the present invention and the method of manufacturing the field effect transistor, gate electrode materials having such work functions that threshold voltages decrease in operations of the MOSFETs of n-channel and p-channel under a supposed low-temperature condition are selected, or gate electrode materials are manufactured while controlling the work functions for an n-channel MOSFET and a p-channel MOSFET, respectively, and gate electrodes are formed by the gate electrode materials in the n-channel MOSFET and the p-channel MOSFET, respectively. For this reason, desired threshold voltages for the n-channel MOSFET and the p-channel MOSFET can be obtained under the supposed low-temperature condition without controlling the threshold voltages by ion implantation in the channels or applying a substrate bias voltage Vsub for controlling the threshold voltages.

In the field effect transistor according to the first embodiment of the present invention, since the substrate bias voltage Vsub is not applied to both the n-channel MOSFET and the p-channel MOSFET, reliability such as hot-carrier resistance is not deteriorated especially in the n-channel MOSFET and a complex circuit configuration can be eliminated.

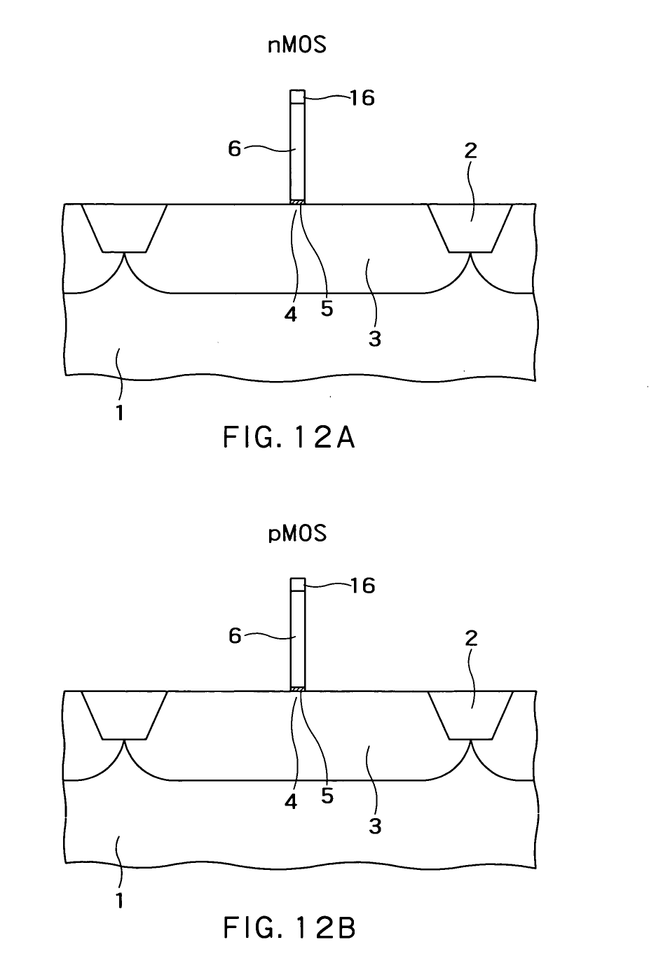

FIGS. 12A and 12B to FIGS. 16A and 16B are sectional views showing steps of manufacturing a field effect transistor according to the second embodiment of the present invention. Respective Figs. A show n-channel MOSFETs, and respective Figs. B show p-channel MOSFETs.

In the field effect transistor according to the second embodiment of the present invention, it is assumed that a substrate bias voltage Vsub for controlling a threshold voltage is not applied to the n-channel MOSFET. As a gate electrode material for forming a gate electrode of the n-channel MOSFET, a gate electrode material having the work function described with reference to FIG. 3A such that the threshold voltage decreases in an operation of the MOSFET under a supposed low-temperature condition is selected, or a gate electrode material is manufactured while controlling the threshold voltage. On the other hand, in the p-channel MOSFET, it is assumed that the substrate bias voltage Vsub for controlling a threshold voltage is applied in an operation of the MOSFET under the supposed low-temperature condition. As gate electrode materials for forming gate electrodes of the p-channel MOSFET, conventionally used gate electrode materials are selected, or coordinated and manufactured. The gate electrodes are formed by the gate electrode materials, respectively.

As the gate electrode material of the p-channel MOSFET, for example, polysilicon (poly-Si), polysilicon germanium (poly-SiGe), or the like is used as a gate electrode material.

As shown in FIGS. 12A and 12B, the steps of manufacturing a field effect transistor performed until the gate electrode 6 is formed are almost the same as the steps of manufacturing a field effect transistor according to the first embodiment shown in FIGS. 4A and 4B. However, in this case, as the gate electrode material, a gate electrode material for forming the gate electrode 6 of the p-channel MOSFET, e.g., polysilicon germanium (poly-SiGe) is used to form the gate electrodes 6 of the n-channel MOSFET and the p-channel MOSFET. In the steps of manufacturing a field effect transistor according to the second embodiment of the present invention, a cap film 16 made of silicon nitride (SiN) is formed on the upper surface portion of the gate electrode 6 in advance. Even in the steps of manufacturing a field effect transistor according to the second embodiment, several forming methods can be used as a method of forming a gate electrode. However, only one example of the several forming methods is described here.

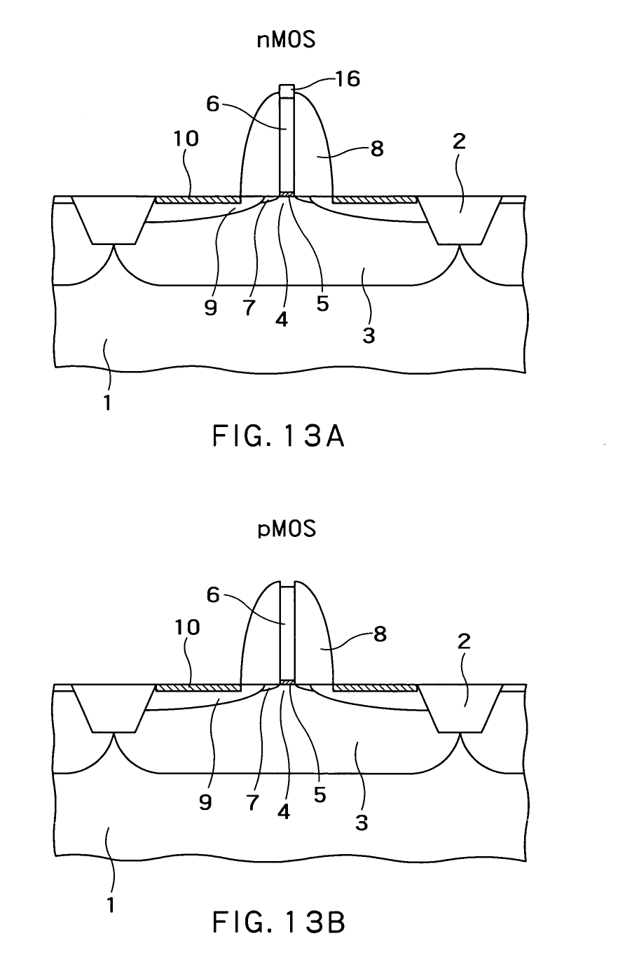

The cap film 16 formed on the upper surface portion of the gate electrode 6, as shown in FIGS. 13A and 13B, is removed from only a p-channel MOSFET region by etching. Thereafter, as in the steps of manufacturing a field effect transistor according to the first embodiment of the present invention shown in FIGS. 5A and 5B and FIGS. 6A and 6B, a shallow diffusion layer 7 is formed, and a gate side wall 8 is formed. The cap film 16 in the p-channel MOSFET region may be removed after the gate side wall 8 is formed.

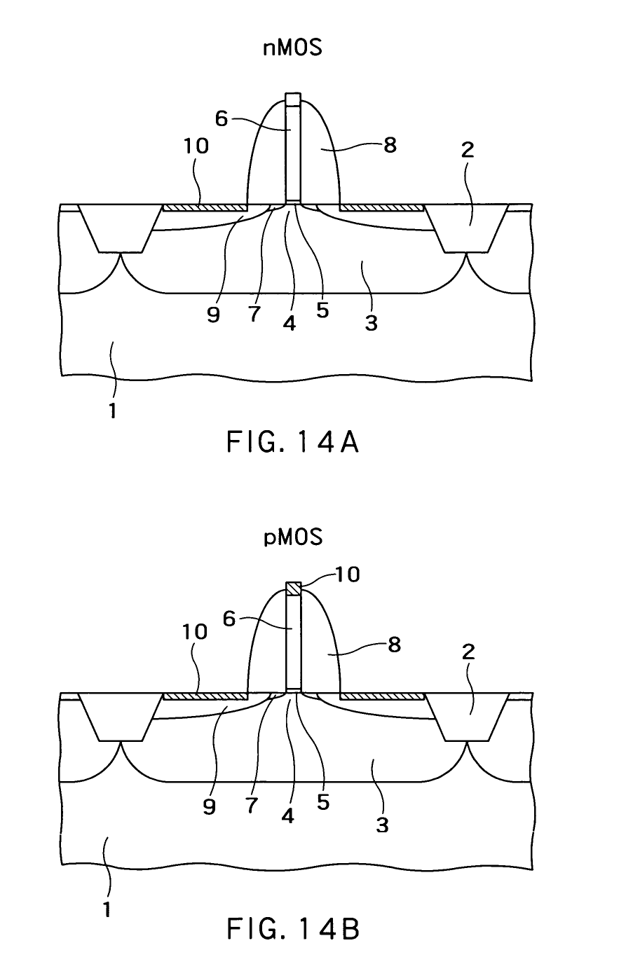

After the gate side wall 8 is formed, as in the steps of manufacturing a field effect transistor according to the first embodiment of the present invention shown in FIGS. 7A and 7B, a high-concentration diffusion layer 9 and a silicide layer 10 are formed. In the steps of manufacturing a field effect transistor according to the second embodiment of the present invention, since the upper surface portion of the gate electrode 6 in the p-channel MOSFET region is exposed, as shown in FIGS. 14A and 14b, the silicide layer 10 is also formed on the upper surface portion of the gate electrode 6.

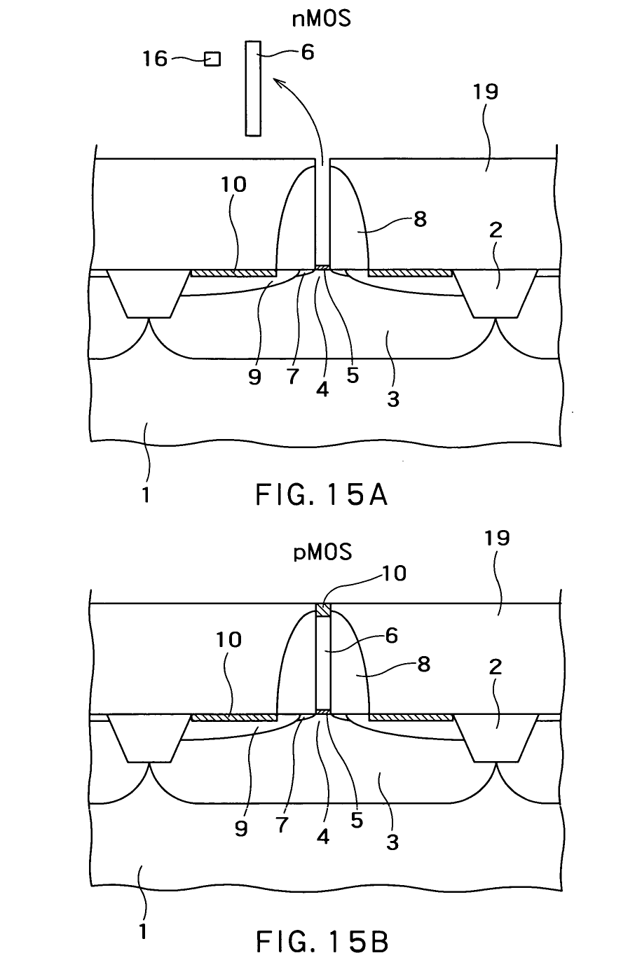

After the silicide layer 10 is formed, as shown in FIGS. 15A and 15B, an interlayer film 19 is formed, and CMP is performed by using the cap film 16 formed on the upper surface portion of the gate electrode 6 in the n-channel MOSFET region as a stopper film. After CMP is performed, the cap film 16 and the gate electrode 6 are removed from only an n-channel MOSFET region by RIE or the like.

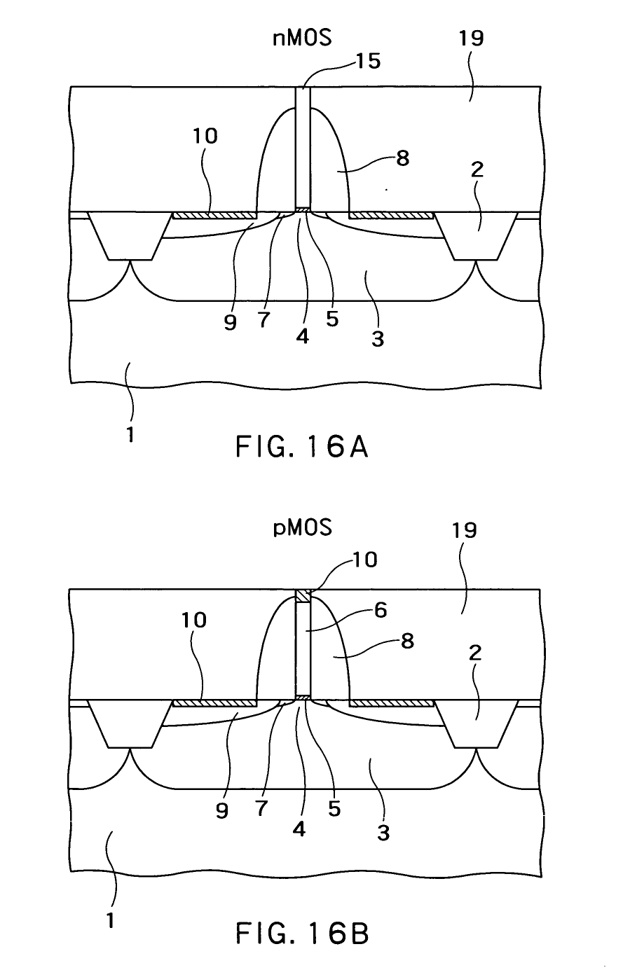

Thereafter, as shown in FIGS. 16A and 16B, a gate electrode material having an appropriate work function is buried into the n-channel MOSFET by, e.g., a Damascene process to make it possible to form a gate electrode 15.

As described above, in the field effect transistor according to the second embodiment of the present invention and the method of manufacturing the field effect transistor, for n-channel MOSFET, gate electrode material having such work function that threshold voltages decrease in an operation under a supposed low-temperature condition is selected, respectively, or gate electrode material is manufactured while controlling the work function, and the gate electrode 15 is formed by the gate electrode material. For this reason, a desired threshold voltage for the n-channel MOSFET can be obtained under the supposed low-temperature condition without controlling the threshold voltage by ion implantation in the channel or applying a substrate bias voltage Vsub for controlling the threshold voltage.

In the field effect transistor according to the second embodiment of the present invention, since the substrate bias voltage Vsub is not applied to the n-channel MOSFET, reliability such as hot-carrier resistance can be prevented from being deteriorated.

On the other hand, for the p-channel MOSFET, a conventionally used gate electrode material is selected as a gate electrode material for forming a gate electrode, or coordinated and manufactured. The gate electrode is formed by the gate electrode material. In the p-channel MOSFET, a substrate bias voltage Vsub for controlling a threshold voltage is applied in an operation of the MOSFET under a supposed low-temperature condition. For this reason, reliability such as hot-carrier resistance of the p-channel MOSFET can be improved.

As described above, the field effect transistor according to each of the embodiments of the present invention and the method of manufacturing the field effect transistor can provide a field effect transistor which realize an accurate and reliable low temperature operation without applying a substrate bias voltage.

What is claimed is:

1. A field effect transistor which is supposed to be operated under a temperature condition at 300 K or less, comprising:
an n-channel field effect transistor having a gate electrode formed by a gate electrode material having a work function WFn of less than 4.05.

2. The field effect transistor according to claim 1, wherein the work function WFn is related to a temperature Temp and satisfies the following inequality:
4.05−(300−Temp)×0.08/100<WFn<4.05−(300−Temp)×0.05/100.

3. The field effect transistor according to claim 1, further comprising:
a p-channel field effect transistor to which a substrate bias voltage for controlling a threshold voltage is applied in an operation under said temperature condition.

4. A field effect transistor which is supposed to be operated under a temperature condition at 300 K or less, comprising:
an n-channel field effect transistor having a gate electrode formed by a gate electrode material having a work function WFn which is less than a numerical value corresponding to an energy Ec at a lower end of a conduction band in an energy band.

5. The field effect transistor according to claim 4, further comprising:
a p-channel field effect transistor to which a substrate bias voltage for controlling a threshold voltage is applied in an operation under said temperature condition.

6. A field effect transistor which is supposed to be operated under a temperature condition at 300 K or less, comprising:
a p-channel field effect transistor having a gate electrode formed by a gate electrode material having a work function WFp of more than 5.17.

7. The field effect transistor according to claim 6, wherein the work function WFp is related to a temperature Temp and satisfies the following inequality:
5.17+(300−Temp)×0.05/100<WFp<5.17+(300−Temp)×0.08/100.

8. A field effect transistor which is supposed to be operated under a temperature condition at 300 K or less, comprising:
a p-channel field effect transistor having a gate electrode formed by a gate electrode material having a work function WFp which exceeds a numerical value corresponding to an energy Ev at an upper end of a valence band in an energy band.

9. A method of manufacturing a field effect transistor which is supposed to be operated under a temperature condition at 300 K or less, wherein a gate electrode of an n-channel field effect transistor is formed by a gate electrode material having a work function WFn of less than 4.05.

10. The method of manufacturing a field effect transistor according to claim 9, wherein the work function WFn is related to a temperature Temp and satisfies the following inequality:
4.05−(300−Temp)×0.08/100<WFn<4.05−(300−Temp)×0.05/100.

11. A method of manufacturing a field effect transistor which is supposed to be operated under a temperature condition at 300 K or less, wherein a gate electrode of an n-channel field effect transistor is formed by a gate electrode material having a work function WFn which is less than a numerical value corresponding to an energy Ec at a lower end of a conduction band in an energy band.

12. A method of manufacturing a field effect transistor which is supposed to be operated under a temperature condition at 300 K or less, wherein a gate electrode of a p-channel field effect transistor is formed by a gate electrode material having a work function WFp of more than 5.17.

13. The method of manufacturing a field effect transistor according to claim 12, wherein the work function WFp is related to a temperature Temp and satisfies the following inequality:
5.17+(300−Temp)×0.05/100<WFp<5.17+(300−Temp)×0.08/100.

14. A method of manufacturing a field effect transistor which is supposed to be operated under a temperature condition at 300 K or less, wherein a gate electrode of a p-channel field effect transistor is formed by a gate electrode material having a work function WFp which exceeds a numerical value corresponding to an energy Ev at an upper end of a valence band in an energy band.
